(19) United States
(12) Patent Application Publication
(10) Pub. No.: US 2001/0001437 A1
(43) Pub. Date: May 24, 2001

(54) HOLDING UNIT VACUUM MACHINING DEVICE AND METHOD OF MANUFACTURING ELEMENT

(75) Inventors: MASAAKI MIKAMI, KAWASAKI-SHI (JP); MASAAKI WATANABE, KAWASAKI-SHI (JP); MASAYOSHI MIZOGUCHI, KAWASAKI-SHI (JP); SHUUEI SIMOJOH, KAWASAKI-SHI (JP)

Correspondence Address: ARMSTRONG,WESTERMAN, HATTORI,, MCLELAND & NAUGHTON, LLP, 1725 K STREET, NW, SUITE 1000, WASHINGTON, DC, 20006, US

(73) Assignee: FUJITSU LIMITED,

(21) Appl. No.: 09/206,319

(22) Filed: Dec. 7, 1998

(30) Foreign Application Priority Data
Jul. 15, 1998 (JP) 10-200216

(51) Int. Cl. C23C 14/00; C23F 1/00

(52) U.S. Cl. 204/192.34; 204/192.11; 204/192.32; 204/298.15; 216/66; 427/523; 427/569; 156/345; 118/728; 118/721; 118/503

(57) ABSTRACT

The holding unit of a vacuum machining device is capable of preventing a work piece from being excessively heated and capable of stably machining the work piece. The holding unit comprises: a holder for holding a work piece; a pressing member for pinching the work piece with the holder; and a heat insulating member being provided to the holder, the heat insulating member contacting the work piece to restrict heat conduction thereto.

### BACKGROUND OF THE INVENTION

The present invention relates to a holding unit of a vacuum machining device and a method of manufacturing an element.

In a process of manufacture semiconductor elements, wafer processing steps, e.g., forming film layers on a wafer, etching the film layers, are frequently executed. During the wafer processing steps, the wafer is held and its surface is exposed to be machined.

A summarized structure of an ion milling device for etching a work piece is shown in FIG. 3. A symbol 10 stands for a vacuum chamber; a symbol 12 stands for an ion gun; a symbol 14 stands for a grid; a symbol 16 stands for a holder for holding the work piece 20; and a symbol 18 stands for a pressing ring for pinching the work piece 20 with the holder 16.

The pressing ring 18 presses an outer edge of the work piece 20 to pinch and hold the work piece 20 with the holder 16. Inner diameter of the pressing ring 18 is designed according to outer diameter of the work piece 20. To make an exposed surface of the work piece 20 broader, width of the pressing ring 18, which presses the outer edge of the work piece 20, is designed 2-3 mm. The pressing ring 18 is fixed to the holder by screws 19.

A process of etching patterns on the work piece by ion milling will be explained with reference to FIGS. 4A-4C. In FIG. 4A, a film layer 6 to be etched is formed on a substrate 5 of a work piece, and a resist layer 7, which has been formed into a prescribed shape, is formed on the film layer 6. The resist layer 7 exposes parts of the film layer 6, which will be removed by etching. In this state, the film layers 6, which has been masked with the resist layer 7, is etched, by ion milling, so as to remove the film layer 7 of the exposed parts (see FIG. 4B). In FIG. 4C, the resist layer 7 has been removed after the ion milling. The film layer 6, whose shape corresponds to the shape of the resist layer 7, is left on the surface of the substrate 5.

In the above describe ion milling treatment, ions are radiated toward not only the work pieces 20 but also the pressing ring 18, which is headed for the ion gun 12 (see FIG. 3). Upon colliding ions, the work piece 20 and the pressing ring 18 are heated.

If the work piece 20 is excessively heated, the resist 7 changes in quality, so that the film pattern cannot be correctly formed. Thus, in the conventional ion milling device, cooling water is introduced into the holder 16 so as to cool the work piece 20.

Since the pressing ring 18 is fixed to the holder 16 by the screws 19, the pressing ring 18 is slightly cooled by the water in the holder 16. But contact area between the screws 19 and the pressing ring 18 is quite small, so the water in the holder 16 cannot effectively cool the pressing ring 18.

With this structure, the pressing ring 18 of the conventional device is excessively heated, so that parts of the work piece 20, which are directly pressed by the pressing ring 18, will be also excessively heated. By excessively heating the work piece 20, the resist 7 is partially fused together with the work piece 20.

If the resist 7 is fused together with the work piece 20, the edge part of the work piece 20, on which the resist 7 is partially left, cannot be used for manufacturing elements, so that efficiency of manufacturing the elements is reduced. A plurality of the work pieces 20 are simultaneously processed in the ion milling device, so it is inefficient for manufacturing the elements to make the disusable parts in each work piece 20.

In a device for forming the film layers on the work piece, the work piece 20 is pinched by the holder 16 and the pressing ring 18 so as to set and be processed as well as the ion milling device. So, the device also has disadvantages of excessively heating the pressing ring 18 and badly influencing the work piece 20.

### SUMMARY OF THE INVENTION

The present invention is invented to solve the problems occurred by excessively heating the work piece in the vacuum machining device, e.g., the ion milling device, the film forming device. Objects of the present invention are to provide a holding unit of a vacuum machining device and a method of manufacturing an element, which are capable of preventing the work piece from being excessively heated and capable of stably machining the work piece.

To achieve the objects, the present invention has following constitutions.

The holding unit of the present invention comprises: a holder for holding a work piece; a pressing member for pinching the work piece with the holder; and a heat insulating member being provided to the holder, the heat insulating member contacting the work piece to restrict heat conduction thereto.

Another holding unit of the present invention comprises: a holder for holding a work piece; a pressing member for pinching the work piece with the holder; and a heat insulating member being provided to the pressing member, the heat insulating member contacting the work piece to restrict heat conduction thereto.

In the holding unit, the pressing member may be formed into a ring shape, and an inner edge of the pressing member may contact the work piece.

In the holding unit, the insulating member may be wholly circumferentially provided on a contact face of the pressing member, which is capable of contacting the work piece.

The method of the present invention comprises the steps of: pinching the work piece by a holder and a pressing member, wherein a heat insulating member contacts the work piece; and processing the work piece, which is pinched between the holder and the pressing member, in a vacuum machining device.

In the method, film layers may be formed on the work piece in the processing step.

In the method, the work piece may be etched in the processing step.

In the holding unit and the method of the present invention, the work piece is not excessively heated by heat conduction from the pressing member even if the pressing member is heated in the vacuum machining device. Therefore, changing quality of the resist layer, etc., which are formed on the surface of the work piece, can be prevented; yield of manufacturing the elements can be improved; and the work piece can be correctly machined.

### BRIEF DESCRIPTION OF THE DRAWINGS

Embodiments of the present invention will now be described by way of examples and with reference to the accompanying drawings, in which:

FIGS. 1A and 1B are perspective views of a holding unit of an embodiment;

FIG. 2 is a sectional view of the holding unit;

FIG. 3 is an explanation view showing a summarized structure of an ion milling device; and

FIGS. 4A-4C are explanation views showing a process of etching by ion milling.

### DETAILED DESCRIPTION OF THE PREFERRED EMBODIMENTS

Preferred embodiments of the present invention will now be described in detail with reference to the accompanying drawings.

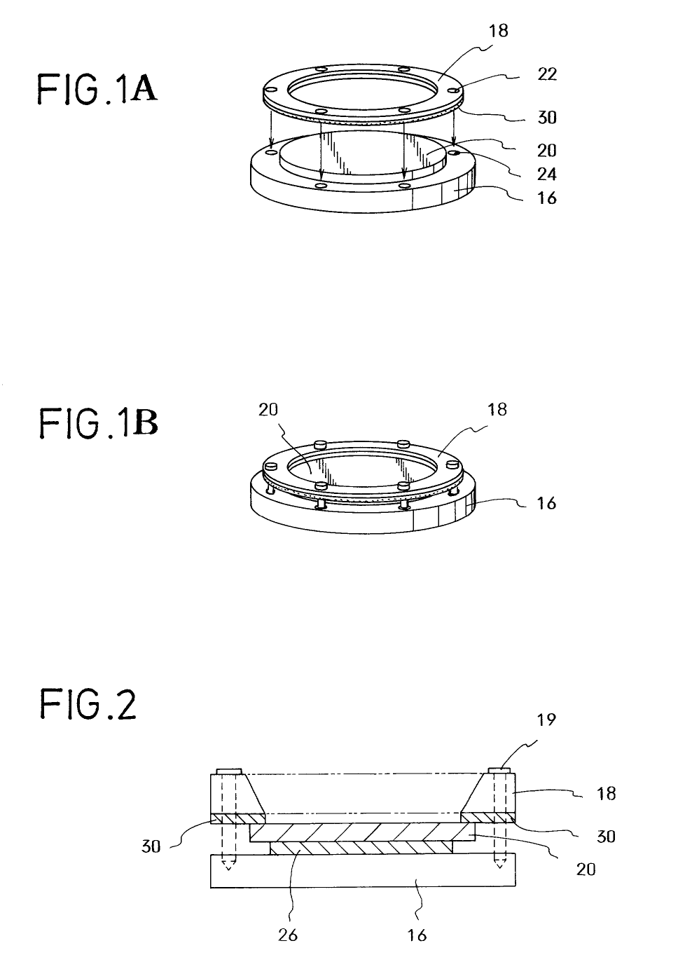

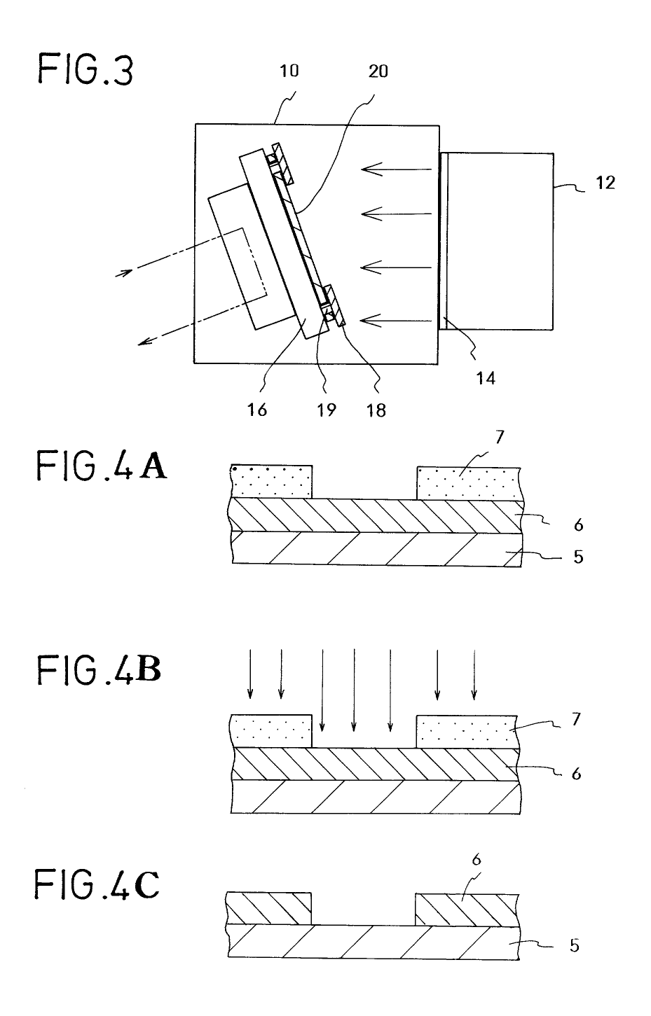

FIGS. 1A and 1B are perspective views of a holding unit of the present embodiment. In the figures, a symbol 16 stands for a holder for holding a work piece 20, and a symbol 18 stands for a pressing ring for pressing an outer edge of the work piece 20 toward the holder 16 to pinch the work piece 20. Basic structures of the holder 16 and the pressing ring 18 are as same as those of the conventional device shown in FIG. 3. The work piece 20 shown in FIG. 1 is a wafer. The holder 16 and the pressing ring 18 are made of metals. Inner diameter of the pressing ring 18 is 2-3 mm shorter than diameter of the wafer 20.

The pressing ring 18 has through-holes 22 through which screws 19 are respectively pierced; the holder 16 has screw holes 24.

In FIG. 1B, the pressing ring 18 is fixed to the holder 16 by the screws 19 so as to hold the work piece 20 on the holder 16. The work piece 20 is held by the manner as well as the conventional device.

A characteristic point of the present embodiment is the structure of the pressing ring 18. Namely, there is provided a heat insulating member 30, e.g., rubber, on a contact face of the pressing ring 18, which is capable of contacting the work piece 20. By the heat insulating member 30, heat conduction from the pressing ring 18 to the work piece 20 can be restricted.

FIG. 2 is a sectional view showing a state of holding the work piece 20 on the holder 16 by the pressing ring 18. The heat insulating member 30 is stuck on a bottom face of the pressing ring 18, so the work piece 20 is pressed onto the holder 16 by the heat insulating member 30.

By providing the heat insulating member 30 between the pressing ring 18 and the work piece 20, the heat generated in the pressing ring 18 cannot be directly conducted to the work piece 20, so that changing quality of the resist, etc., which are formed on the work piece 20, can be prevented.

The pressing ring 18 presses an outer edge of the work piece 20 to hold the work piece 20 on the holder 16, so the heat insulating member or members should be provided to a specific part or parts of the pressing ring 18, which are capable of contacting the work piece 20. In the present embodiment, the bottom face of the pressing ring 18 is wholly covered with the heat insulating member 30, but the bottom face of the pressing ring 18 may be partially covered with the heat insulating member 30. By providing the heat insulating member 30, the work piece 20 can be securely held. A plurality of theheat insulating members 30 may be arranged in the circumferential direction with regular separations.

The heat insulating member 30 is provided to restrict the direct heat conduction from the pressing ring 18 to the work piece 20 when the pressing ring 18 is excessively heated. Therefore, various materials, which are capable of fully insulating the heat conduction, can be employed as the heat insulating member. For example, resin materials, e.g., silicone rubber, glass wool, etc. may be employed as the heat insulating member 30. Heat conductivity of the heat insulating member 30 is lower than that of the holder 16 and the pressing ring 18. Thickness of the heat insulating member 30 may be designed according to the heat conductivity between the pressing ring 18 and the work piece 20. In some cases, temperature in the vacuum machining device is very high, so the heat insulating member 30 should be made of a material, which has enough heat-resisting property and which generates no gas when the heat insulating member 30 is heated. For example, in the case of machining the wafer 20 whose diameter is about 100-150 mm and whose thickness is about 2-4 mm, thickness of the heat insulating member 30 may be about 1 mm.

In FIG. 2, a symbol 26 stands for a supporting member provided on an upper face of the holder 16. The work piece 20 is pinched and held between the supporting member 26 and the heat insulating member 30 of the pressing member 18. The supporting member 26 is provide so as to securely hold the work piece 20. If the heat insulating member 30, which is provided to the pressing ring 18, is made of a material having slight cushioning property, e.g., rubber, the screws 19 can securely hold the work piece 20.

Cooling water may be introduced into the holder 16 to cool the holder 16 and the work piece 20. By cooling the holder 16, the pressing ring 18 can be slightly cooled via thescrews 19.

In the holding unit of the vacuum machining device of the present embodiment, the direct heat conduction from the pressing ring 18 to the work piece 20 is restricted even if the pressing ring 18 is excessively heated while machining, e.g., ion milling; the changing quality of the resist layer, etc., which are formed on the surface of the work piece 20, can be prevented.

In the case of employing the conventional holding unit, in which the work piece 20 is directly pressed and pinched by the pressing ring 18 without the heat insulating member, in the ion milling device, rate of producing bad products is about 14%; by employing the holding unit of the present embodiment, which includes the heat insulating member 30, in the ion milling device, the rate of producing bad products can be reduced to about 1.64%.

Materials of the film layers, which are formed on the work piece, and the resist layer, which is formed for etching the film layers, are selected on the basis of their heat-resisting properties and processing temperature of the vacuum machining device. In the case that the processing temperature is high and in the case that the specific part or parts of the pressing ring 18, which contact the work piece 20, are partially excessively heated, it is advantageous to employ the holding unit of the present invention. The holding unit of the present invention can be realized by attaching the heat insulating member 30 to the pressing ring 18, so the conventional holding unit can be used.

Note that, the vacuum machining device is used for not only forming and processing the film layers but also manufacturing liquid crystal displays, etc.. The holding unit of the present invention may be employed in many cases in which a work piece is held by the pressing member and machined in the vacuum machining device.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and ranging of equivalency of the claims are therefore intended to be embraced therein.

What is claimed is:

1. A holding unit of a vacuum machining device, comprising:
a holder for holding a work piece;
a pressing member for pinching the work piece with said holder; and
a heat insulating member being provided to said holder, said heat insulating member contacting the work piece to restrict heat conduction thereto.

2. The holding unit according to claim 1, wherein said pressing member is formed into a ring shape, and an inner edge of said pressing member contacts the work piece.

3. A holding unit of a vacuum machining device, comprising:
a holder for holding a work piece;
a pressing member for pinching the work piece with said holder; and
a heat insulating member being provided to said pressing member, said heat insulating member contacting the work piece to restrict heat conduction thereto.

4. The holding unit according to claim 3, wherein said pressing member is formed into a ring shape, and an inner edge of said pressing member contacts the work piece.

5. The holding unit according to claim 4, wherein said insulating member is wholly circumferentially provided on a contact face of said pressing member, which is capable of contacting the work piece.

6. A method of manufacturing an element by processing a work piece in a vacuum machining device, comprising the steps of:
pinching the work piece by a holder and a pressing member, wherein a heat insulating member contacts the work piece; and
processing the work piece, which is pinched between said holder and said pressing member, in said vacuum machining device.

7. The method according to claim 6, wherein film layers are formed on the work piece in said processing step.

8. The method according to claim 6, wherein the work piece is etched in said processing step.
